(19) United States
(12) Patent Application Publication
(10) Pub. No.: US 2010/0315777 A1
(43) Pub. Date: Dec. 16, 2010

(54) Weatherproof outdoor plasma/LCD cover

(76) Inventor: Michael Patrick Dreher, Arlington, TX (US)

Correspondence Address: MICHAEL P. DREHER, 2404 SPRINGRIDGE DR., ARLINGTON, TX, 76014, US

(21) Appl. No.: 12/384,886

(22) Filed: Jun. 15, 2009

(51) Int. Cl. H05K 7/20; H05K 5/00

(52) U.S. Cl. 361/695; 361/724

(57) ABSTRACT

A wall mounted or encapsulated apparatus sealed from the elements for outdoor intended use for protection of a “PLASMA” or “LCD” television and or components. It is a fully acrylic housing intended to “weatherproof” and aid in “security” from theft or physical damage. The apparatus would be made of an acrylic fashion with an optional anti-glare version. The apparatus will be clear to allow viewing of the Plasma or LCD screen.

### FIELD OF THE INVENTION

The invention relates generally to the use of electronics outdoors and more particularly the protection from general weather, physical damage and theft prevention.

### BACKGROUND OF THE INVENTION

In this information summary, we will review the distinctive features of the product and the needs it fulfills. The concept of the Weatherproof Outdoor Plasma/LCD Cover is a weatherproof, transparent security cover that would be installed over or covering an outdoor flat panel TV. The apparatus would be rectangular with an open back and a hinged door. The hinged door would attribute the use of a magnetic closure system. A filter holder would be mounted into the top of the apparatus. Built into the apparatus would be a three-way switch labeled off, fan only and fan/thermostat; and molded in cutouts for an RCA or other type of TV port. There would be a weather strip seal between all of the rear edges of the apparatus and the wall on which it is mounted. The apparatus would be available in different sizes to accommodate different TVs. The apparatus is being suggested because it fulfills the need for an acrylic cover that would be installed over a TV to protect it from theft and water damage. The appealing features of the Weatherproof Outdoor Plasma/LCD Cover would be its low cost, security, and weatherproofing. Outdoor (waterproof) TVs are expensive and vulnerable to theft. The apparatus would provide an inexpensive alternative to an outdoor television. The LCD or Plasma TV cover would be purchased separately. The apparatus would be wall mounted over the TV. It would be made of transparent acrylic that would allow the TV to be viewed through the cover. The apparatus would include a door that would swing open to provide access to the remote control or DVD functions. There would be a filter holder molded into the apparatus with a filter included. Additional filters could be purchased separately. The filter would help keep the TV free of moisture and dust. A fan built into the apparatus would help keep the TV cool inside the apparatus. The user could turn the fan on and off manually as desired or allow it to be controlled by thermostat built into the apparatus. Molded in holes would provide access to RCA or other TV port connections. The apparatus would also have a anti theft removal sensor that could be used in conjunction with a security system.

### BRIEF DESCRIPTION OF THE FIGURES

FIG. 1. This is the overall view of the apparatus;

FIG. 2. This is an illustration of the RCA or other type of TV port

FIG. 3. This is an ON/OFF switch with a thermostatically controlled option

FIG. 4. This is a weather shield to keep weather from entering the apparatus or damaging the exhaust fan motor

FIG. 5. This is a mounting bracket to secure the wall mounted version

FIG. 6. This is the molded location where the filter will be placed to keep apparatus and internals free of moisture and dust

FIG. 7. This is an access door for remote control storage or TV controls access

FIG. 8. This is a magnet mounted to aid in secure door closure

FIG. 9. This is an orientation along the rear edge of the apparatus where a weather-stripping seal is installed to deter weather

FIG. 10. This is the location that a pole mount is installed on the fully encapsulating version

FIG. 11. This is a weather shield to keep the filter protected from weather

FIG. 12. This is a UL listed cord set used to plug the apparatus into standard household power

FIG. 13. This is a location point of the anti theft device that can be used in conjunction with a security system

FIG. 14. This is a door handle used to operate the swing style door

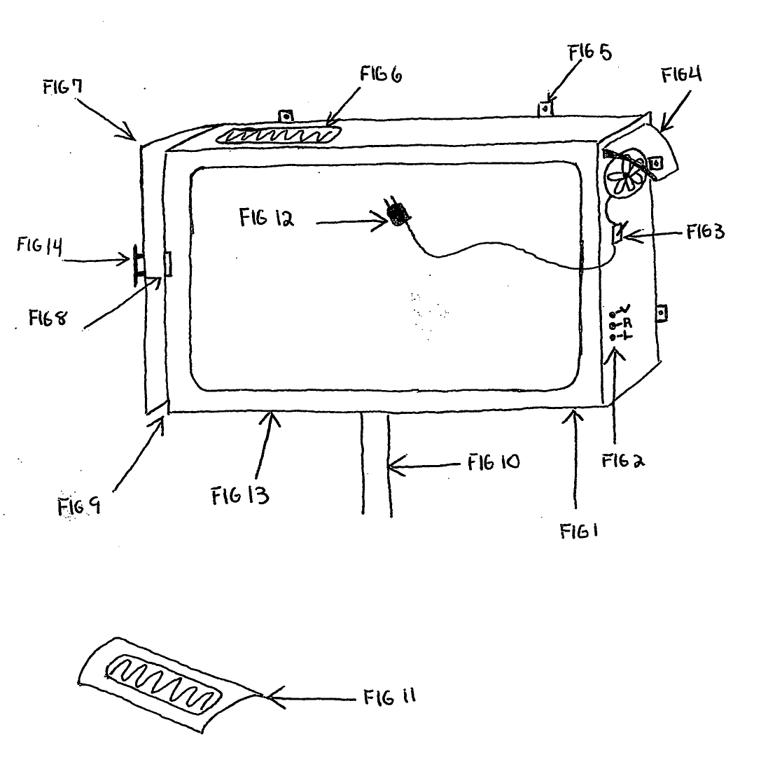

1-18. (canceled)

20) A wall mounted or encapsulated apparatus sealed from the elements for outdoor intended use for protection of a “PLASMA, LCD, or LED television and or components.

21) It is a fully acrylic housing intended to “weatherproof” and aid in “security” from theft or physical damage.

22) The apparatus will be clear to allow viewing of the PLASMA, LCD, or LED screen. The apparatus main functions and design will be described as follows:

23) is dependent from claim (22) containing all the limitations thereof and contains the further limitation; Apparatus has a cooling fan.

24) is dependent from claim (21) containing all the limitations thereof and contains the further limitation; the cooling fan will have a weather guard installed as to not allow general weather from entering the apparatus.

25) is dependent from claim (21) containing all the limitations thereof and contains the further limitation; the apparatus will also have a charcoal filter installed to aid in the removal of moisture and dust throughout the apparatus.

26) is dependent from claim (21) containing all the limitations thereof and contains the further limitation; the filter will also have a weather guard to aid in general weather from entering the apparatus.

27) is dependent from claim (22) containing all the limitations thereof and contains the further limitation; the fan will be controlled by a standard ON/OFF switch with an installed thermostat for automatic operation.

28) is dependent from claim (20) containing all the limitations thereof and contains the further limitation; the apparatus will have an access door as where to access the Plasma or LCD screen.

29) is dependent from claim (20) containing all the limitations thereof and contains the further limitation; the access door has a magnet for closure and a weather stripping seal to keep apparatus internals free of general weather.

30) is dependent from claim (22) containing all the limitations thereof and contains the further limitation; the access door of the apparatus win have a handle/knob used to open and close the access door.

31) is dependent from claim (20) containing all the limitations thereof and contains the further limitation; the wall mounted version will have mounts as to where to secure the apparatus to a wall.

32) is dependent from claim (21) containing all the limitations thereof and contains the further limitation; the wall mounted version will have weather stripping located on the side to be wall mounted to keep apparatus free of general weather.

33) is dependent from claim (22) containing all the limitations thereof and contains the further limitation; the wall mounted version will also be equipped with an anti theft device such as a siren or magnetic sensor installed that can be equipped to link to a home or business security system.

34) is dependent from claim (22) containing all the limitations thereof and contains the further limitation; also IR kits can be sold with the apparatus for adding a external remote receiver to help with remote functionality as the television will be covered by the “Weathertech”

35) is dependent from claim (20) containing all the limitations thereof and contains the further limitation; an encapsulating version will be available to completely surround Plasma, LCD or LED screen.

36) is dependent from claim (20) containing all the limitations thereof and contains the further limitation; an encapsulating version will be equipped with a pole mounted bracket and mounting pole for other than wall mounted applications.

37) is dependent from claim (21) containing all the limitations thereof and contains the further limitation; the apparatus would be made of an acrylic fashion with an optional anti-glare version.
